(19) United States
(12) Patent Application Publication
(10) Pub. No.: US 2024/0405516 A1
(43) Pub. Date: Dec. 5, 2024

(54) SEMICONDUCTOR OPTICAL AMPLIFICATION ELEMENT

(71) Applicant: NEC Corporation, Tokyo (JP)

(72) Inventor: Morio Takahashi, Tokyo (JP)

(73) Assignee: NEC Corporation, Tokyo (JP)

(21) Appl. No.: 18/642,919

(22) Filed: Apr. 23, 2024

(30) Foreign Application Priority Data
May 31, 2023 (JP) 2023-090488

(51) Int. Cl. H01S 5/50; H01S 5/026; H01S 5/10; H01S 5/14

(52) U.S. Cl. CPC H01S 5/50; H01S 5/026; H01S 5/101; H01S 5/141

(57) ABSTRACT

A semiconductor optical amplification element including: a first optical amplification waveguide that amplifies light by using a semiconductor; a second optical amplification waveguide that amplifies light by using the semiconductor; and a loop waveguide reflector that reflects light by using a loop of a waveguide, wherein one end of the first optical amplification waveguide is connected to the loop waveguide reflector, another end of the first optical amplification waveguide and another end of the second optical amplification waveguide are formed with a coplanar anti-reflection termination surface, and one end of the second optical amplification waveguide is formed with an anti-reflection termination surface.

### INCORPORATION BY REFERENCE

This application is based upon and claims the benefit of priority from Japanese patent application No. 2023-090488, filed on May 31, 2023, the disclosure of which is incorporated herein in its entirety by reference.

### TECHNICAL FIELD

The present disclosure relates to a semiconductor optical amplification element.

### BACKGROUND ART

A semiconductor optical amplifier (SOA) for laser oscillation and an SOA for optical amplification (also referred to as a booster optical amplifier (BOA) in order to be distinguished from an SOA for laser oscillation) are used as a semiconductor optical amplification element for a wavelength variable laser. FIG. 7 of Japanese Unexamined Patent Application Publication No. 2017-98362 discloses an optical integrated element including a first SOA and a second SOA, wherein a waveguide-type mirror is connected to the first SOA. Herein, the waveguide-type mirror is a diffraction grating mirror. The first SOA serves for laser oscillation, and the second SOA serves for optical amplification.

### SUMMARY

However, the diffraction grating mirror connected to the first SOA for laser oscillation is wavelength dependent, and is not suitable for an application for achieving an optical gain for achieving laser oscillation in a wide wavelength band, such as a wavelength variable laser. In principle, the diffraction grating mirror is not capable of reflecting entire spontaneous emission light from the first SOA, but is designed in such a way as to achieve reflection in a limited wavelength band (a wavelength band to be used in a wavelength variable laser). Therefore, the spontaneous emission light from the first SOA being out of the used wavelength band is emitted outside a chip without being reflected, and becomes stray light, thereby hindering operation of the wavelength variable laser. Therefore, an example object of the present disclosure is to provide a semiconductor optical amplification element suitable for a wavelength variable laser.

In an example aspect of the present disclosure, a semiconductor optical amplification element includes a first optical amplification waveguide configured to amplify light by using a semiconductor, a second optical amplification waveguide configured to amplify light by using the semiconductor, and a loop waveguide reflector configured to reflect light by using a loop of a waveguide, wherein one end of the first optical amplification waveguide is connected to the loop waveguide reflector, and another end of the first optical amplification waveguide and another end of the second optical amplification waveguide are formed with a coplanar anti-reflection termination surface, and one end of the second optical amplification waveguide is formed with an anti-reflection termination surface.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a block diagram illustrating a configuration of a semiconductor optical amplification element according to an example embodiment; and

FIG. 2 is a schematic diagram illustrating a configuration of a semiconductor optical amplification element according to the example embodiment.

### EXAMPLE EMBODIMENT

Hereinafter, an example embodiment of the present disclosure is be described with reference to the drawings. However, the disclosure according to the claims is not limited to the following example embodiment. Further, not all configurations described in the example embodiment may be essential as a solution to the problem. For clarity of explanation, the following description and the drawings are omitted or simplified as appropriate. In each of the drawings, identical elements are denoted by the same reference sign, and redundant description is omitted as necessary.

### (Description of Semiconductor Optical Amplification Element According to Example Embodiment)

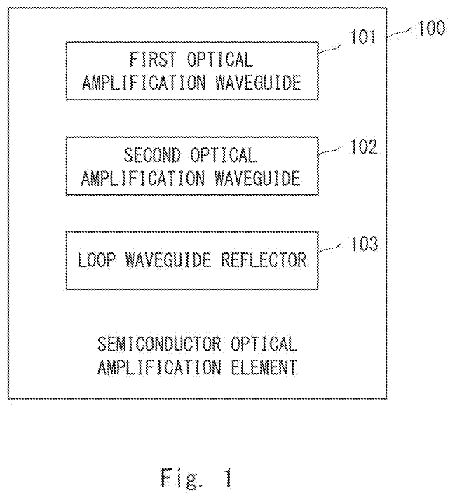

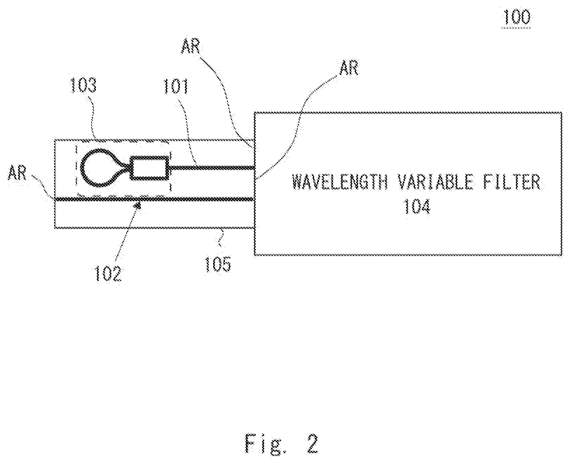

FIG. 1 is a block diagram illustrating a configuration of a semiconductor optical amplification element according to an example embodiment. FIG. 2 is a schematic diagram illustrating the configuration of the semiconductor optical amplification element according to the example embodiment. Referring to FIGS. 1 and 2, the semiconductor optical amplification element according to the example embodiment is described. A semiconductor optical amplification element 100 is an element that amplifies light by using a semiconductor and emits laser light.

As illustrated in FIGS. 1 and 2, the semiconductor optical amplification element 100 includes, in a semiconductor chip 105, a first optical amplification waveguide 101 (SOA), a second optical amplification waveguide 102 (BOA), and a loop waveguide reflector 103. As further illustrated in FIG. 2, the semiconductor optical amplification element 100 includes a wavelength variable filter 104 attached to the semiconductor chip 105.

The semiconductor chip 105 and the optical amplification waveguide are made of, for example, a semiconductor such as InP and GaAs, and an impurity (such as Al and P) that is intentionally added. By forming the first optical amplification waveguide 101 on the same semiconductor chip 105 as the second optical amplification waveguide 102, the semiconductor optical amplification element 100 can be made compact. Further, by forming the first optical amplification waveguide 101 on the same semiconductor chip 105 as the second optical amplification waveguide 102, it is possible to form a waveguide that can efficiently amplify light of the same wavelength.

The first optical amplification waveguide 101 is a laser oscillation semiconductor optical amplifier that amplifies light by using a semiconductor. The first optical amplification waveguide 101 is used, for example, to oscillate light having a wavelength near infrared light (wavelength of about 1500 nm). One end of the first optical amplification waveguide 101 is connected to the loop waveguide reflector 103. An anti-reflection termination surface (AR (anti-reflection) film) is formed on the other end of the first optical amplifying waveguide 101. The other end of the first optical amplification waveguides 101 is connected to the wavelength variable filter 104. Therefore, light from the first optical amplification waveguide 101 enters the wavelength variable filter 104 through the anti-reflection termination surface. By forming an optical resonator in which only light of a specific wavelength is selected by the wavelength variable filter 104 and is returned to the first optical amplification waveguide 101, the first optical amplification waveguide 101 achieves an optical gain equal to or higher than an optical resonator internal loss, thereby performing laser oscillation. Further, a laser using the first optical amplification waveguide 101 can change a wavelength of laser oscillated light by changing and controlling the wavelength selected by the wavelength variable filter 104.

The second optical amplification waveguide 102 is an optical output semiconductor optical amplifier that amplifies, by using a semiconductor, laser light partially extracted from the wavelength variable laser using the first optical amplification waveguide 101. One end of the second optical amplification waveguide 102 is formed with an anti-reflection termination surface. In addition, the other end of the second optical amplification waveguide 102 is formed with an anti-reflection termination surface that is coplanar with the first optical amplification waveguide 101. The other end of the second optical amplification waveguide 102 is connected to the first optical amplification waveguide 101. Therefore, the second optical amplification waveguide 102 amplifies light incident from the other end while transmitting the light to the one end. Laser light is emitted from the one end of the second optical amplification waveguide 102.

The loop waveguide reflector 103 is an optical element that reflects light by using a configuration in which two output sides of a directional coupler or a multimode interference (MMI) waveguide having two inputs and two outputs or one input and two outputs are loop-connected by a waveguide. Internal light of the wavelength variable laser is internally amplified by the first optical amplification waveguide while reciprocating inside the laser resonator formed by the loop waveguide reflector 103 and a reflector in the wavelength variable filter 104, and reaches laser oscillation. Light incident on the loop waveguide reflector 103 is split into one and the other, passes through the waveguide, and returns to the first optical amplification waveguide 101. Since optical path lengths for the two beams of light after being split are the same, the loop waveguide reflector 103 can multiplex the beams of light while matching a phase. Therefore, in order to maximize a reflectance, each of the beams of light after being split desirably has an intensity of 50%. Therefore, coupling between the loop waveguide reflector 103 and the first optical amplification waveguide 101 is desirably made by using an MMI waveguide by which wavelength dependency can be reduced, but a directional coupler may be used.

The wavelength variable filter 104 is an optical element for changing the laser oscillation wavelength of the wavelength variable laser using the first optical amplification waveguide 101 to any wavelength. By selecting any wavelength of the laser light reciprocates between the first optical amplification waveguide 101 and the wavelength variable filter 104, single-mode laser oscillation at any wavelength can be achieved.

According to the above-described configuration, a semiconductor optical amplification element suitable for a wavelength variable laser is provided.

The present disclosure is not limited to the above-described example embodiment, and can be appropriately modified without departing from the spirit. For example, in the present disclosure, the first optical amplification waveguide 101 and the second optical amplification waveguide 102 are formed on the same semiconductor chip 105. However, a third optical amplification waveguide that is a laser semiconductor optical amplifier and a fourth optical amplification waveguide that is an optical output semiconductor optical amplifier may further be formed on the same semiconductor chip 105.

An example advantage according to the above-described example embodiment is that a semiconductor optical amplification element suitable for a wavelength variable laser is provided.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

The whole or part of the example embodiments disclosed above may be described as, but not limited to, the following supplementary notes.

### (Supplementary Note 1)

A semiconductor optical amplification element, including:
a first optical amplification waveguide that amplifies light by using a semiconductor;
a second optical amplification waveguide that amplifies light using the semiconductor; and
a loop waveguide reflector that reflects light by using a loop of a waveguide; wherein
one end of the first optical amplification waveguide is connected to the loop waveguide reflector, another end of the first optical amplification waveguide and another end of the second optical amplification waveguide are formed with a coplanar anti-reflection termination surface, and one end of the second optical amplification waveguide is formed with a anti-reflection termination surface.

### (Supplementary Note 2)

The semiconductor optical amplification element according to supplementary note 1, wherein the first optical amplification waveguide is formed on the same semiconductor chip as the second optical amplification waveguide.

### (Supplementary Note 3)

The semiconductor optical amplification element according to supplementary note 1, wherein another end of the first optical amplification waveguide is connected to a wavelength variable filter.

### (Supplementary Note 4)

The semiconductor optical amplification element according to supplementary note 1, wherein the first optical amplification waveguide is a laser semiconductor optical amplifier, and the second optical amplification waveguide is an optical output semiconductor optical amplifier.

### (Supplementary Note 5)

The semiconductor optical amplification element according to supplementary note 4, wherein the first optical amplification waveguide is connected to the second optical amplification waveguide.

### (Supplementary Note 6)

The semiconductor optical amplification element according to supplementary note 1, wherein the loop waveguide reflector is connected to the one end of the first optical amplification waveguide by using a 1×2 directional coupler.

### (Supplementary Note 7)

The semiconductor optical amplification element according to supplementary note 1, wherein the loop waveguide reflector is connected to the one end of the first optical amplification waveguide by using a 1×2 multi-mode-interference (MMI) waveguide.

What is claimed is:

1. A semiconductor optical amplification element comprising:
a first optical amplification waveguide configured to amplify light by using a semiconductor;
a second optical amplification waveguide configured to amplify light by using the semiconductor; and
a loop waveguide reflector configured to reflect light by using a loop of a waveguide, wherein
one end of the first optical amplification waveguide is connected to the loop waveguide reflector, another end of the first optical amplification waveguide and another end of the second optical amplification waveguide are formed with a coplanar anti-reflection termination surface, and one end of the second optical amplification waveguide is formed with an anti-reflection termination surface.

2. The semiconductor optical amplification element according to claim 1, wherein the first optical amplification waveguide is formed on the same semiconductor chip as the second optical amplification waveguide.

3. The semiconductor optical amplification element according to claim 1, wherein another end of the first optical amplification waveguide is connected to a wavelength variable filter.

4. The semiconductor optical amplification element according to claim 1, wherein
the first optical amplification waveguide is a laser semiconductor optical amplifier, and
the second optical amplification waveguide is an optical output semiconductor optical amplifier.

5. The semiconductor optical amplification element according to claim 4, wherein the first optical amplification waveguide is connected to the second optical amplification waveguide.

6. The semiconductor optical amplification element according to claim 1, wherein the loop waveguide reflector is connected to the one end of the first optical amplification waveguide by using a 1×2 directional coupler.

7. The semiconductor optical amplification element according to claim 1, wherein the loop waveguide reflector is connected to the one end of the first optical amplification waveguide by using a 1×2 multi-mode-interference (MMI) waveguide.
